(19) United States
(12) Patent Application Publication
(10) Pub. No.: US 2026/0073952 A1
(43) Pub. Date: Mar. 12, 2026

(54) BACKSIDE METAL TRACKS FOR SIGNAL CARRYING AND METHOD OF MANUFACTURE THEREOF

(71) Applicant: NVIDIA Corporation, Santa Clara, CA (US)

(72) Inventors: Cagri Erbagci, Pittsburgh, PA (US); Lalit Gupta, Fremont, CA (US)

(21) Appl. No.: 18/830,165

(22) Filed: Sep. 10, 2024

(51) Int. Cl. G11C 5/06; H10B 10/00; H01L 23/528

(52) U.S. Cl. CPC G11C 5/063; H10B 10/125; H10B 10/18; H10W 20/427; H10W 20/435

(57) ABSTRACT

Electrical device including a substrate having a frontside surface and a backside surface and a back-side insulating layer with back-side metal tracks therein, the back-side insulating layer located on the backside surface. At least a portion of at least one of the back-side metal tracks is connected to a signal source to carry a global signal along the portion of the at least one of the back-side metal tracks towards a signal receiver. A method of manufacture including providing: substrate, forming back-side insulating layer on backside surface of substrate and back-side metal tracks therein. Providing a signal source, a signal receiver and connecting at least a portion of at least one of the back-side metal tracks to signal source the portion carrying global signal from the signal source along the portion of towards signal receiver.

### TECHNICAL FIELD

This application is directed, in general, to electrical devices using back-side metal tracks to carry signals, and a method of manufacturing such devices.

### BACKGROUND

As technology nodes advance with the emergence of gate-all around (GM) transistors and dispensing with the need for an nwell layer and its taps. This in turn, shrinks the standard memory cell height and consequently limits the metal tracks available in a standard cell pitch. Although advance processes introduce back-side power delivery to eliminate the power grid on the front- side of the substrate, the number of front-side metal tracks can still be constrained due to the dense global and local interconnects and their need for electrical shielding.

### SUMMARY

One aspect provides an electrical device. The electrical device includes a substrate having a frontside surface and a backside surface and a back-side insulating layer with back-side metal tracks therein, the back-side insulating layer located on the backside surface. At least a portion of at least one of the back-side metal tracks is connected to a signal source to carry a global signal along the portion of the at least one of the back-side metal tracks towards a signal receiver.

Another aspect is a method of manufacturing an electrical device. The method includes providing a substrate having a frontside surface and a backside surface, forming a back-side insulating layer on the backside surface and forming back-side metal tracks in the back-side insulating layer. The method includes providing a signal source of the device, the signal source capable of producing a global signal and providing a signal receiver of the device, the signal receiver capable of receiving the global signal, The method includes connecting at least a portion of at least one of the back-side metal tracks to the signal source of the device, wherein the portion of the least one of the back-side metal track can carry the global signal from the signal source along the portion of the at least one of the back-side metal tracks towards the signal receiver.

### BRIEF DESCRIPTION

Reference is now made to the following descriptions taken in conjunction with the accompanying drawings, in which:

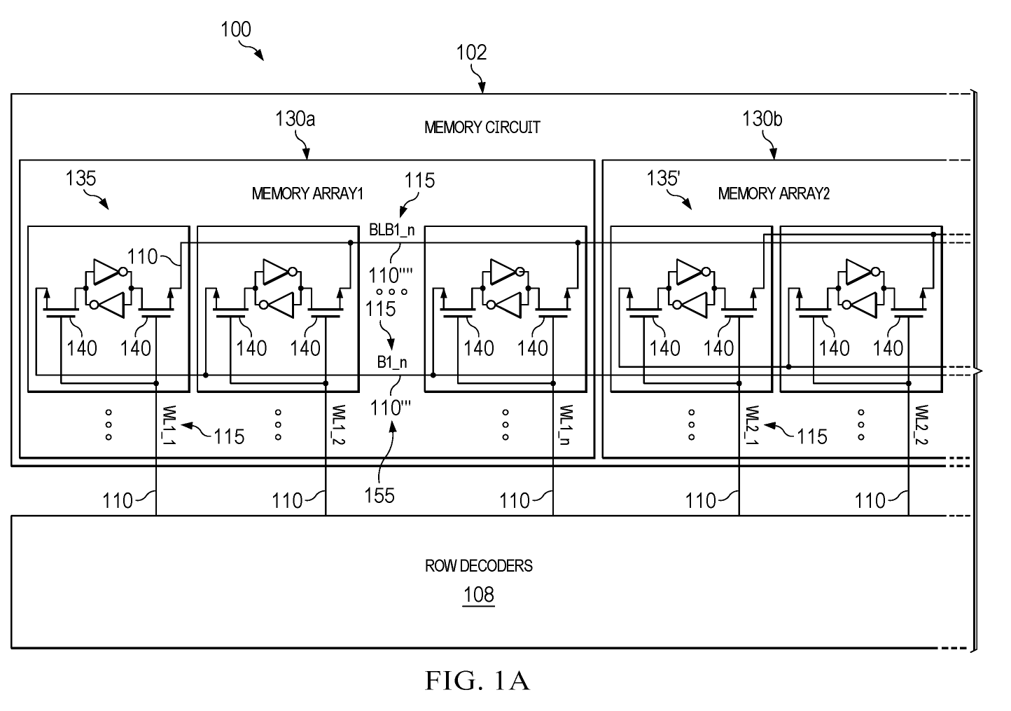

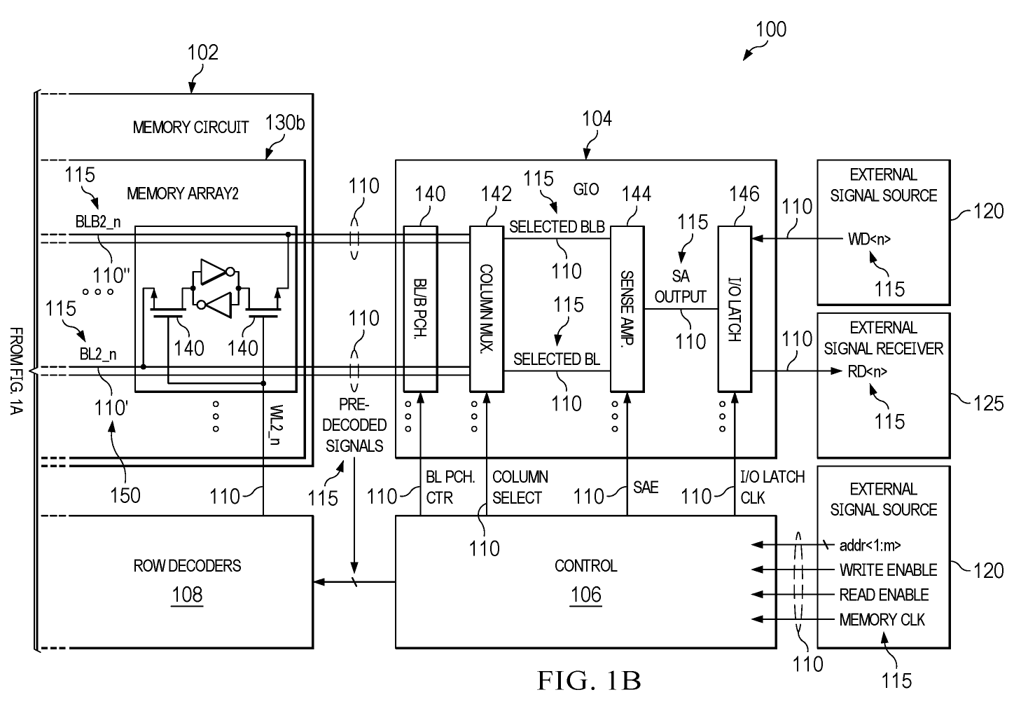

FIGS. 1A and 1B present a schematic block diagram view of an example electrical device of the disclosure showing metal tracks therein and there-between example circuits of the device;

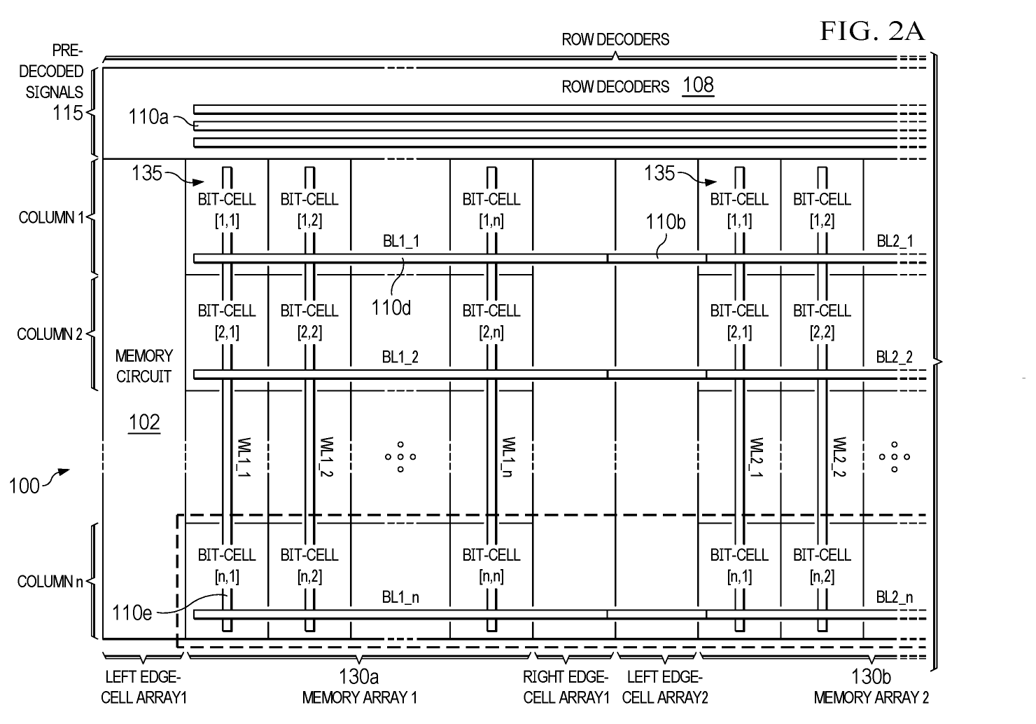

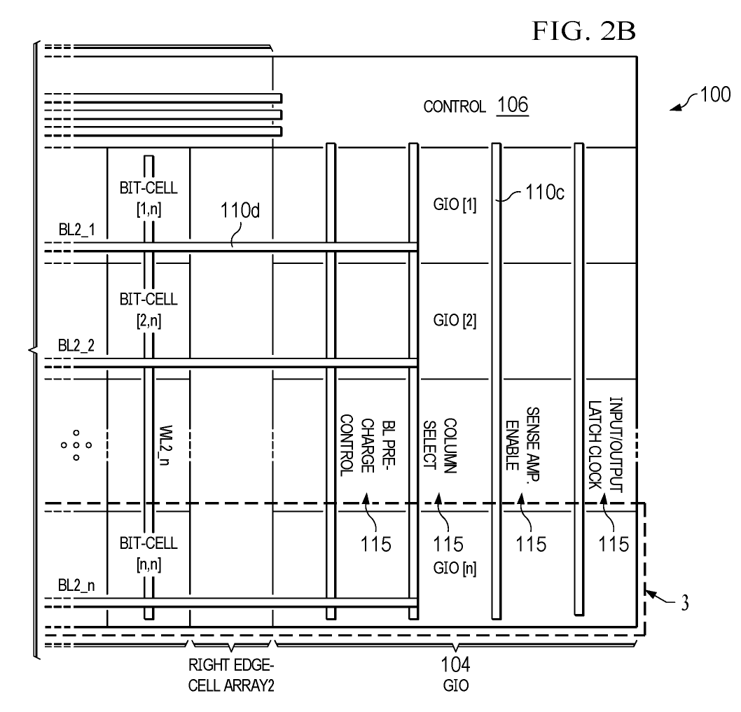

FIGS. 2A and 2B present a schematic block diagram view of example embodiments of the first and second memory array circuits and the general input output circuit, such as depicted in FIGS. 1A and 1B, with an example arrangement of back-side metal tracks and front-side metal tracks therein and there-between;

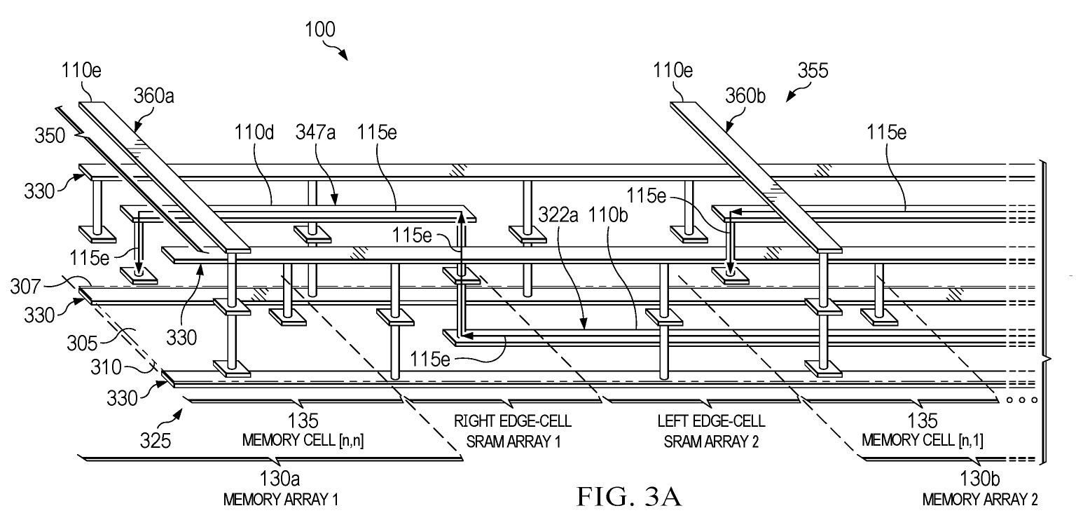

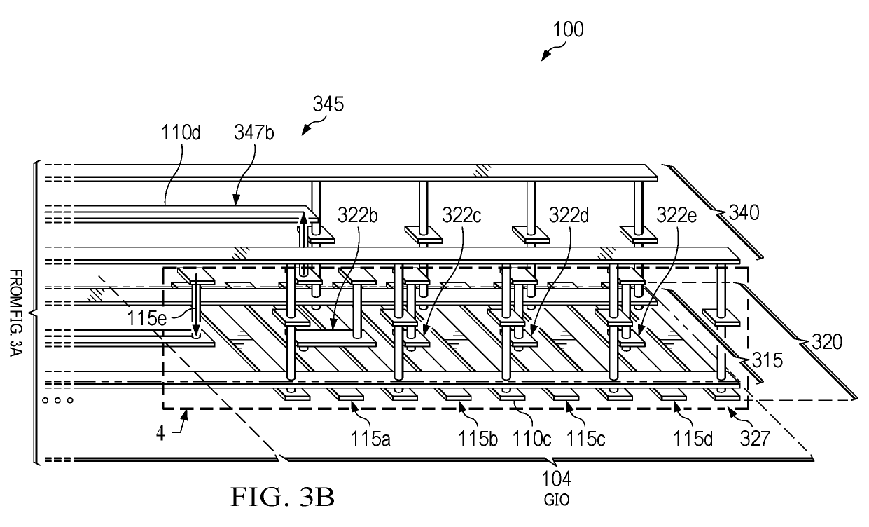

FIGS. 3A and 3B present an exploded perspective view of a portion of the first and second memory array circuits and the general input output circuit, analogous to that depicted in FIGS. 2A and 2B, with an example arrangement of the back-side metal tracks and the front-side metal tracks therein and there-between;

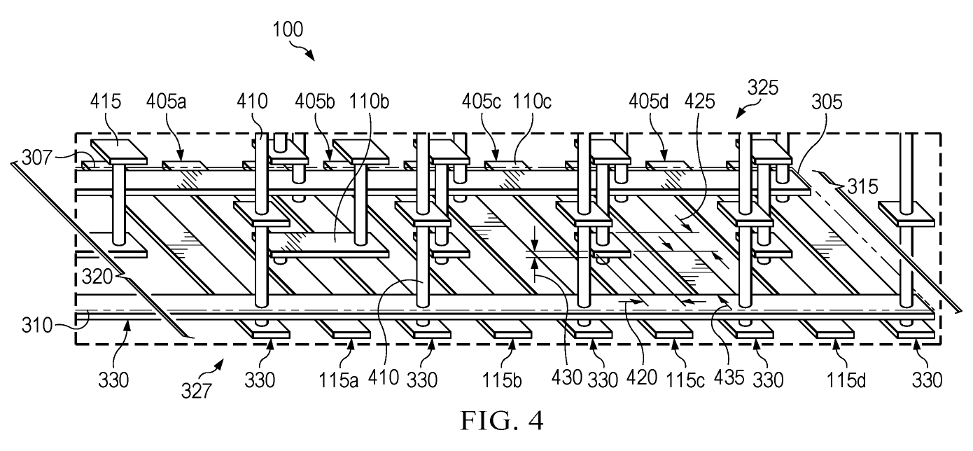

FIG. 4 presents an exploded perspective view of a portion of the general input output circuit, such as depicted in FIG. 3A and 3B, illustrating different levels of the back-side metal tracks;

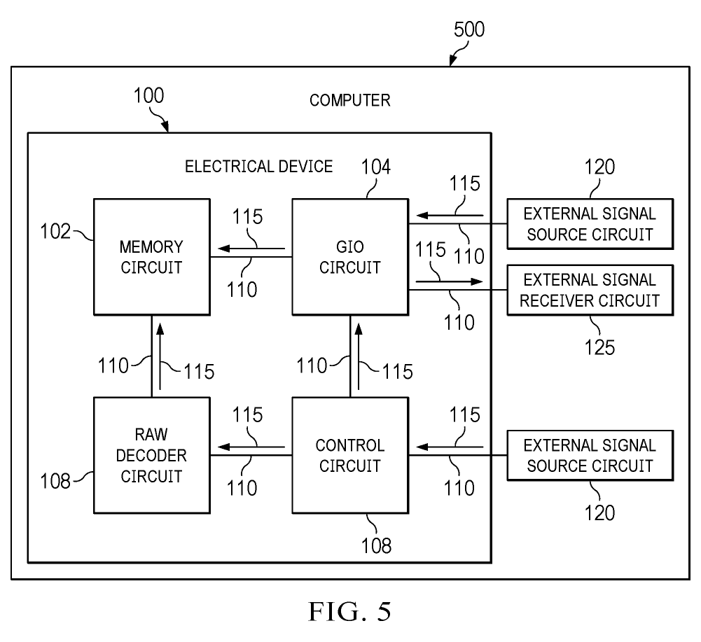

FIG. 5 presents a block diagram of a computer having one or more electrical circuits that include any embodiments of the electrical device such as disclosed in the context of FIGS. 1A-4; and

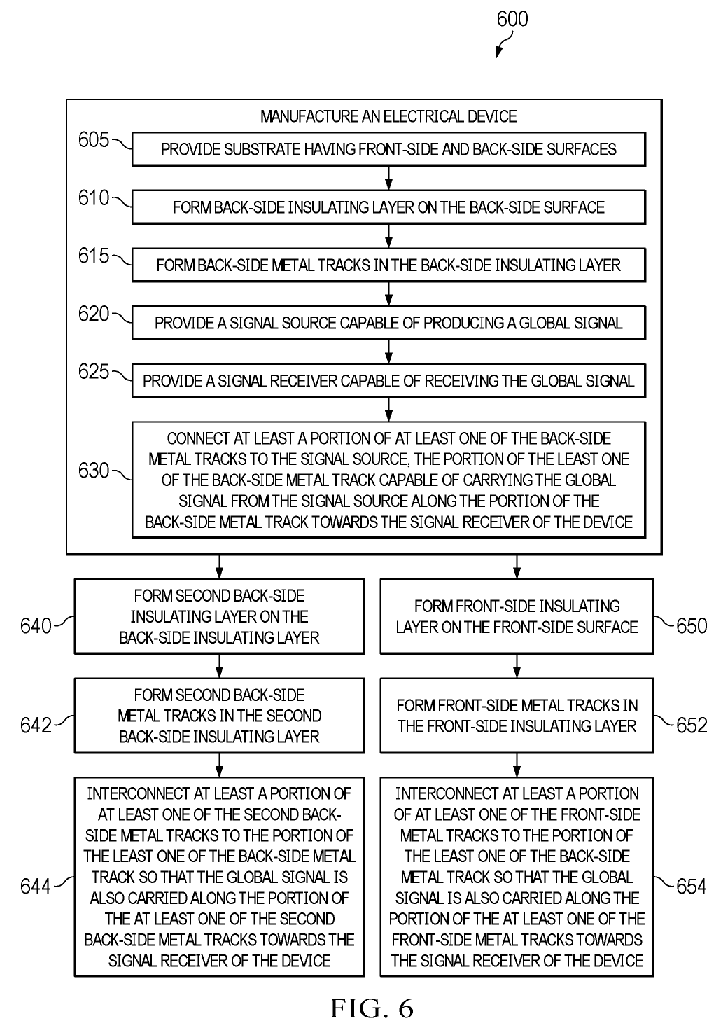

FIG. 6 presents a flow diagram of a method of manufacturing the electrical device including any embodiments of the device disclosed in the context of FIGS. 1A-5.

### DETAILED DESCRIPTION

Although design rules to place back-side metal tracks for power delivery help reduce or eliminate the use of front-side metal tracks for power delivery, the number of such front-side metal tracks available to carry global signals such as bit-lines (BL), word lines (WL), or pre-charge control signals, with appropriate reduced resistance and shielding, can still constrain placement and routing (PnR) circuit designs.

Embodiments of the disclosure follow from our idea to use at least portions of back-side metal tracks to carry at least a portion of such global signals to enhance signal performance without necessarily modifying the metal stacks in a memory circuit design. Is it not obvious that back-side metal tracks could be used to carry signals because this appears to violate design rules that specifically dictate that back-side metal tracks to be used for power delivery. Surprisingly, however, we discovered that by using just a portion of the back-side metal tracks to provide at least a portion of route for the signals, we could reduce reliance signal routing being provided solely by front-side metal tracks, and thereby mitigate potential degraded performance due to increase electrical resistance or signal cross-talk. That is, while using some back-side metal tracks for non-power uses, such as signal carrying, at first appears to violate a design rule, by using just a portion of the back-side metal tracks to carry signals, the remaining back-side metal tracks can still provide the device power as required under the design rules.

It was also surprising that using back-side metal tracks designed to carry power could be repurposed to carry signals because such tracks are designed as power delivery structures. For instance, the back-side metal tracks designed to carry power are thinner than that desired to carry signals, because the spacing between adjacent tracks is smaller than desired for maximizing signal performance by reducing signal cross-talk. Using portions of back-side metal tracks for signal routing in turn, can free-up some portions of front-side metal tracks to give more room for top level routing or eliminate more remote upper level front-side metal tracks (e.g., one or more of front-side metal level 4, M4, through metal level 6, M6, in some embodiments) thereby reducing masking and other fabrication costs, or avoiding the need to take measures to introduce blockage to avoid coupling between such higher metal levels.

One embodiment of the disclosure is an electrical device.

FIGS. 1A and 1B present a schematic block diagram view of an example electrical device 100 of the disclosure showing metal tracks therein and there-between example circuits of the device.

Any embodiments of the device 100 could include any one or more of the following electrical circuits as familiar to one of ordinary skill in the pertinent art: a memory circuit 102, a general input output (GIO) circuit 104, a control circuit 106 or a row decoder circuit 108. Anyone or all of such circuits can include metal tracks (generally metal track 110) to carry signals (generally, global signal 115) within each of the circuits (e.g., any of circuits 102, 104, 106, 108) or between one circuit (e.g., any one of circuits 102, 104, 106, 108) and another other circuit (e.g., any other of circuits 102, 104, 106, 108), wherein at least a portion of at least one of the metal tracks 110 is a back metal track, as further disclosed herein. As further disclosed herein, any such back-side metal tracks can be connected to a signal source which can be from any such circuits (e.g., any of circuits 102, 104, 106, 108) or to a signal source, that is external to the device 100 (e.g., external source circuit 120), to carry the global signal 115 along the back-side metal track towards a signal receiver which can correspond to another of the circuits (e.g., any other of circuits 102, 104, 106, 108) or towards a signal receiver that is external to the device (e.g., external receiver circuit 125).

The term global signal as used herein means any electrical signal sent from one circuit component of the electrical device to another circuit component of the device or sent within such circuit components.

For example, the memory circuit 102 can include a plurality memory arrays (e.g., generally array 130; first memory array 130a and second memory array 130b) and each memory array can include plurality of memory cells (e.g., FIGS. 1A-2B. generally bit-cell 135; any SRAM bit-cell) which includes transistors 140 arranged to form the circuit of the memory cell. E.g., the transistors can be NMOS transistors, such as gate-all around (GAA) transistors, arranged as six-transistor, eight-transistor circuits or other multi-transistor circuit cells, and, one skilled in the pertinent art would understand how other types of memory cells could be used additionally or alternatively. The global signal 115 can be any of bit-line signals or complementary bit-line signals (e.g., bit-line write voltage signals b1_n, blb1_n, respectively, or bl2_n, blb2_n, respectively), word-line signals (e.g., word line voltage signals wl1_1, wl1_2,…wll_n, wl2_1, wl2_1, wl2_2,…wl2_n), carried by metal tracks 110, any of which can include portions of back-metal tracks, to the transistors 140 of any of the memory cells 135.

For example, the GIO circuit 104 can include anyone or all of a bit-line pre-charge control circuit (bl/b pch 140), a column multiplexer select circuit (column MUX 142), a sense amplifier circuit (Sense Amp 144) and an input/output latch clock circuit (I/O latch 146). The global signal 115 can be an input output signal or a clock signal, a selected bit-line signal (selected bl) and selected complementary signal (selected blb), or a selected amplified output signals (SA output), carried by metal tracks 110, any of which can include portions of back-metal tracks, between any such circuits (e.g., to or from any of circuit 140, 142, 144) or between the memory cells 135 of the memory circuit 102.

For example, the control circuit 106 can send the global signal 115 as anyone or all of: a bit-line pre-charge control signal (bl pvh ctr) to the bit-line pre-charge control circuit 140, a column select control signal (column select) to the column multiplexer select circuit 142, a sense amplifier enable control signal (SAE) to the sense amplifier circuit 144 or an input latch input/output latch clock control signal (I/O/Latch clk) to the input/output latch clock circuit 146. Any such signals can be carried by metal tracks 110, any of which can include portions of back-metal tracks, between the control circuit 106 and any of these circuits of the GIO circuit 104.

For example, the global signal 115 can be any or all of the word line signals (e.g., wl1_1, wl1_2,…wll_n, wl2_1, wl2_1, wl2_2,…wl2_n) from the row decoder circuit 108, carried by metal tracks 110, any of which can include portions of back-metal tracks, to the memory cells 135 of the memory circuit 102.

For example, the global signal 115 can be from one or more external signal source circuits 120 and send a write data signal (WD_{<n>}) to the GIO circuit 104 or add data signal (e.g., in some embodiments, via metal tracks arranged as a bus to carry multi-bit signals; add_{<1, m>}), a write enable signal, a read enable signal or a memory clock signal (Memory clk) to the control circuit 106. An external receiver 125 can receive the global signal 115 as a read data signal (RD_{<n>}) from the GIO circuit 104. Any such signals can be carried by metal tracks 110, any of which can include portions of back-metal tracks, between the external source circuit 120 or the external receiver 125 and the GIO circuit 104 or the control circuit 106.

FIGS. 2A and 2B present a schematic block diagram view of an example embodiment of the first and second memory array circuits 130a, 130b of the memory circuit 102, and of the general input output circuit 104, such as depicted in FIGS. 1A and 1B, with example metal tracks 110 therein and there-between. As illustrated non-limiting examples, some of the metal tracks 110 can be back-side metal tracks (e.g., back-side metal tracks 110a, 110b) and others of the metal tracks can be front-side metal tracks (e.g., front-side metal tracks 110c, 110d). For example, as illustrated, some of the back-side metal tracks 110a (e.g., in some embodiments arranged as a bus to carry multi-bit signals) can be connected to carry the pre-decoded signals 115 from the control circuit 106 to the row decoders circuit 108, others of the back-side metal tracks 110b can be connected to carry the bit-line signals or complementary bit-line signals (e.g., b1_n, blb1_n, bl2_n, blb2_n) between one memory array 130a and another memory array 130b, and still others of the back-side metal tracks 110c can be connected to carry the bit-line pre-charge control signal 115 to the bit-line pre-charge control circuit 140, the column select control signal 115 to the column multiplexer select circuit 142, the sense amplifier enable control signal 115 to the sense amplifier circuit 144 or an input latch input/output latch clock control signal 115 to the input/output latch clock circuit 146 of the GIO circuit 104.

For example, as illustrated, some front-side metal tracks 110d can be connected to carry the bit-line signals or the complementary bit-line signals (e.g., b1_n, blb1_n, bl2_n, blb2_n) between one memory array 130a and another memory array 130b, and still others of the front-side metal tracks 110e can be connected to carry the word line signals (e.g., wl1_1, wl1_2,…wll_n, wl2_1, wl2_1, wl2_2,…wl2_n) from the row decoder circuit 108 to the memory cells 135 of the memory arrays 130a, 130b of the memory circuit 102. Based on the present disclosure, one skilled in the pertinent art would appreciate that these connection arrangements are only examples, and, any of the bit-line signals or the complementary bit-line signals or the word line signals could be carried in whole or in part by back-metal tracks.

FIGS. 3A and 3B presents an exploded perspective view of a portion of the first and second memory array circuits 130a, 130b and the general input output circuit 104, of the device 100, analogous to that depicted in FIGS. 2A and 2B, showing back-side metal tracks and front-side metal tracks connected to carry signals 115 therein and there-between. FIG. 4 presents an exploded perspective view of a portion of the general input output circuit, such as depicted in FIGS. 3A and 3B, illustrating different levels of the back-side metal tracks.

With continuing reference to FIGS. 1A-4 throughout, the device 100 can include a substrate 305 having a frontside surface 307 and a backside surface 310. A backside insulating layer (insulating layer 315) located on the backside substrate surface (e.g., directly on backside surface 307) can include a back-side metal track (e.g., by convention, BM0, back-side metal track 110b) located in the backside insulating layer 315. In some embodiments, additionally or alternatively, another backside insulating layer (insulating layer 320) can be located on the backside substrate surface (e.g., indirectly on the back side surface 310) by being located on the first backside insulating layer 315 with a different back-side metal track (e.g., by convention, BM1, back-side metal track 110c) located in the second backside insulating layer 320.

Based on the present disclosure, one skilled in the pertinent art would appreciate how, in some embodiments, further multiple back-side insulating layers could similarly be located on the back-side substrate surface (on the first back-side insulating layer 315 and on the second backside insulating layer 320) with different additional sets of back-side metal tracks (e.g., BM2, BM3, BM4 etc.) therein, or in some embodiments, the back-side metal tracks could be part of the metal tracks of the raw decoder circuit 108 (e.g., metal track 110a, FIG. 2) or part of other metal tracks as described in the context of FIGS. 1A and 1B.

At least a portion (e.g., any one or more of portions 322a, 322b, 322c, 322d, 322e) of at least one of the back-side metal tracks (e.g., any of back-metal tracks 110a, 110b, 110c) can be connected to a signal source (e.g., signals from GIO circuit 104, control circuit 106, raw decoders circuit 108, or external signal source circuit 120 of the device 100) to carry a global signal (e.g., any one of signals 115a, 115b, 115c, 115d, 115e) along the back-side metal track towards a signal receiver (e.g., signal to memory circuit 102, GIO circuit 104, control circuit 106, raw decoders circuit 108, external signal receiver 125 of the device 100).

As illustrated, in some embodiments, the back-metal track and their portions carrying the signal or signals 115 can be part of a set (e.g., BM0 back-side metal track set 325) of the parallel-arranged back-metal tracks in the insulating layer (e.g., layer 315). In some such embodiments, alternating one of the back-metal tracks in the set can be connected to an electrical ground (e.g., VDD/GND 330), e.g., to increase signal isolation and decrease signal cross-talk between back-metal tracks carrying different signals.

As illustrated in FIGS. 3A, 3B and 4, some embodiments of the device 100 additionally or alternatively, further include another backside insulating layer (e.g., layer, 320) located on the backside substrate surface indirectly on the back side surface 310 by being located on the first backside insulating (e.g., layer 315) and having another set (e.g., second BM1 back-side metal track set 327) of the back-side metal tracks (e.g., any others of BM1 back-side metal tracks 110a, 110b, 110c) located therein.

In some such embodiments, at least a portion (e.g., any of portions 405a…405d) of at least a second one of the back-side metal tracks (e.g., BM1 back-side metal track 110c) in the other set 327 is connected to another of the signal source (e.g., and of the signal sources 104, 106, 108, 120), to carry the global signal (e.g., any of the signals 115a, 115b, 115c, 115d) along the second one back-side metal track towards another of the signal receiver (e.g., any of the signal receivers 102, 104, 106, 108, 125).

In some such embodiments, the back-side metal tracks (e.g., BM0, back-side metal track 110b; BM1, back-side metal track 110c) located in adjacent back-side insulating layers, (e.g., layers 315, 320) can be arranged to have their lengths (e.g., lengths 420, 405, of back-side metal tracks 110b, 110c, respectively) running orthogonal to each other, such as illustrated in FIGS. 3A, 3B and 4, e.g., to reduce signal coupling between the metal tracks.

In some such embodiments, parallel-arranged alternating ones of the back-metal tracks 110c of the other set (e.g., alternating ones of the back-side metal tracks 110c of the second set 327) in the second back side insulating layer (BM1 layer, 320) can be connected to an electrical ground (e.g., VDD/GND 330, e.g., the same electrical ground 330 that the alternating ones of the back-metal tracks in the first back-side set 325 are connected to), e.g., to increase signal isolation and decrease signal cross-talk between back-side metal tracks carrying different signals.

As illustrated in FIGS. 3A and 3B, any such embodiments of the device 100, can further include a front-side insulating layer (e.g., layer 340) with front-side metal tracks (e.g., by convention, M0, front-side metal tracks 110d) therein, the front-side insulating layer located on the front-side surface 307. At least a portion (e.g., portions 347a or 347b) of at least one of the front-side metal tracks (e.g., M0 front-side metal track 110d) can be connected to a signal source (e.g., any of circuits 104, 106, 108, or signal source circuit 120), of the device 100 to carry a global signal (e.g., any of b1_n, blb1_n, bl2_n, blb2_n signals 115e or other signals 115a, 115b, 115c, 115d) along the front-side metal track towards a signal receiver (e.g., any of circuits 102, 104, 106, 108, or receiver 125) of the device 100.

In some embodiments, the at least one front-side metal track can be part of a set (e.g., front-side set 345) of the front-side metal tracks (e.g., others of front-side parallel-arranged metal tracks 110d) located in the front-side insulating layer 340.

In some such embodiments, alternating ones of the front-side metal tracks in the set of front-side metal tracks 110 in the front-side insulating layer 340 (e.g., M0 first front-side metal track set 345) can be connected to an electrical ground (e.g., the same electrical ground 330 that the alternating ones of the BM0, BM1 back-side metal track sets 325, 327 are connected to), e.g., to increase signal isolation and decrease signal cross-talk between front-side metal tracks carrying different signals.

As also illustrated in FIGS. 3A and 3B, some embodiments of the device 100 can further include a second front-side insulating layer (e.g., layer 350) with front-side metal tracks (e.g., by convention, M1, parallel-arranged front-side metal tracks 110e) therein, the second front-side insulating layer located 350 on the front-side substrate surface 307 (e.g., indirectly on the substrate surface by being on the first front-side insulating layer 340), with another set (e.g., second front-side set 355) of the front-side metal tracks (M1 front-side metal tracks 110e) located therein.

At least a portion (e.g., one or more portions 360a, 360b) of at least one of the front-side metal tracks in the other set (e.g., second set 355 of the front-side metal tracks 110e) can be connected to another of the signal source (e.g., any of signal sources 104, 106, 108, 120), to carry the global signal 115 (e.g., wl1_1, wl1_2,…wll_n, wl2_1, wl2_1, wl2_2,…wl2_n signal 115e, or other of signals 115a, 115b, 115c, 115d) along the one front-side metal track of the other set 355 towards another of the signal receiver (e.g., one or more of circuits 102, 104, 106, 108, 125 signal receiver).

Based on the present disclosure, one skilled in the pertinent arts would understand how, in some embodiments, alternating ones of the parallel arranged front-side metal tracks in the set of front-side metal tracks 110 in the second front-side insulating layer 350 (e.g., second front-side metal track set 355) can be connected to an electrical ground, and, how the front-side metal tracks M0, M1 (e.g., front-side metal tracks 110d, 110e) located in adjacent front-side insulating layers 340, 350 can be arranged to have their lengths running orthogonal to each other, to increase signal isolation and decrease signal cross-talk between front-side metal tracks carrying different signals.

As illustrated in FIGS. 3A and 3B, in some embodiments of the device 100, the global signal, e.g., carried by the at least one back-side metal track, can be carried by multiple different back-side metal tracks and front-side metal tracks that are interconnected with each other to carry the global signal to the signal receiver. As a non-limiting example, a bit line signal 115e (e.g., BL2_n) can be carried from the substrate 305 (e.g., the substrate holding any of signal sources from the circuits 104, 106, 108 thereon) by a portion of a front-side metal track (e.g., portion 347b of front-side metal track 110d) to a memory cell 135 (e.g., memory cell [n,1] ) of a memory array 130b of the memory circuit 102. Or, another bit line signal 115e (e.g., BL1_n) can be carried from the from the substrate 305 along a portion of a back-side metal track (e.g., portion 322a of back-side metal track 110b) to another portion of s front-side metal track (e.g., portion 347a of front-side metal track 110e) to another memory cell 135 (e.g., memory cell [n,n] ) of a memory array 130a of the memory circuit 102. Or, a bit-line pre-charge control signal 115a, a column select control signal 115b, sense amplifier enable control signal 115c or an input latch input/output latch clock control signal 115d can be carried from a signal source (e.g., the GIO circuit 104) by different portions of different back-side metal tracks (e.g., portions 405a, 405b, 405c, 405d, respectively, of back-side metal tracks 110c in a second backside insulating layer 320) to portions of another back-side metal track (e.g., portions 322b, 322c, 322d, 322e, respectively, of back-side metal tracks 110b in a first backside insulating layer 315).

One skilled in the pertinent art would understand how the interconnections between various signal-carrying back-side metal tracks and front-side metal tracks (e.g., interconnections between any of metal tracks 110a, 110b, 110c, 110d, 110e) could be accomplished through the use of via structures 410 and contact pads 415 through and on the substrate 305 and the insulating layers (e.g., any of layers 315, 320, 340, 350) that include such metal tracks.

In some embodiments, some of the backside insulating layers (e.g., layers 315, 320) may not include the back-side metal tracks that are connected to carry carrying the global signal. For instance, in some embodiments, some of the back-side metal tracks (or portions thereof) can be connected to carry electrical power only, or, some of the back-side metal tracks (or portions thereof) can carried signals while other one of the back-side metal tracks (or portions thereof) are connected to carry electrical power.

As illustrated FIGS. 1A and 1B, in some embodiments, one metal track which can be a back-side metal track can carry a signal (e.g., metal track 110’ carrying bit-line bl2_n signal 115) and another metal track which is also a back-side metal track can carry a complement of the signal carried by the one metal track (e.g., metal track 110’’ carrying complementary bit-line blb2_n signal 115), to thereby form a complementary pair 150 of back-side metal tracks carrying complementary signals (e.g., complementary bit line bl2_n, blb2_n signals).

To mitigate differential electrical resistance between the complementary pairs 150 of back-side metal tracks (e.g., BM0, BM1) carrying such bit-line and complementary bit-line signals, the back-side metal tracks of the pair can be arranged to have same dimensions and pathways on and through a back-side insulating layer (e.g., FIGS. 3 and 4, layer 315 or layer 320).

In some embodiments, the complementary pair 150 of the back-side metal tracks can be part of a flying bit-line metal track assembly, where the pair of back-side metal tracks (e.g., in BM0 back-side metal tracks in insulating layer 315) can be coupled to one memory cell (e.g., memory cell 135’) of a memory array (e.g., memory array 130b) of the memory circuit and another such complementary pairs (e.g., FIG. 1, another pair 155 of metal tracks 110’’’ and 110’’’’) can be arranged to, e.g., ‘fly’ over (via M0 front-side metal track pairs in front-side insulating layer 340) or ‘fly’ under (via other back-side metal track pairs in back-side layer BM1 320) to the one memory cell. For instance, signals (e.g., BL1_1, BL_2, … bit-line signals 115e) can be coupled from the GIO circuit 104 via back-side metal tracks alone, or in combination with front-side metal tracks, in such a flying bit-line metal track assembly, to reduce signal electrical resistance compared to using front side metals alone, and also mitigate placement and routing constraints to thereby save PnR resources.

Based on the present disclosure, one skilled in the pertinent art would appreciate how such complementary pairs 150, 155 of metal tracks could further include interconnected portions of different back-side metal tracks or front-side metal tracks, e.g., to further mitigate potential degraded performance in the transmission of such signals due by reducing electrical resistance and signal cross-talk.

In some embodiments, some or all of structural parameters of the length, width, thickness and spacing of the portions of the back-side metal tracks and the insulating layer in which these tracks are in, may be specified by the design rules of a foundry. Therefore the choices on where and how to structure the back-side metal tracks to carry global signals may be limited. In other embodiments, some or all of these structural parameters may be part of new design rules that consider and optimize the physical characteristics of the signal-carrying back-side metal tracks (e.g., length, width, thickness and separation) and as such, represent newly recognized result-effective variables that can be adjusted to reduce resistance as balanced with increasing back-side metal track density in an insulating layer.

As non-limiting examples, in some such embodiments, the portions (e.g., any of portions 322a…322e or of portions 405a…405d) of the back-side metal tracks (e.g., back-side metal track 110b or 110c, respectively) can have a length value (e.g., length 420) in a range from 1 to 50 µm. For example, in some embodiments of the memory circuit 102 a row of 16 memory cells may range from 16 µm to 50 µm depending on the size of transistors forming the memory cells 135, and the length back-side metal track can be adjusted to match this length.

As further non-limiting examples, in some such embodiment, portions of the back-side metal tracks can have a width value (e.g., width 425) in a range from 20 to 100 nm. Such portions of the back-side metal tracks can have a thickness value (e.g., thickness 430) in a range from 10 to 50 nm. Such portions of the back-side metal tracks can be separated from adjacent ones of the back-side metal tracks by a gap distance value (e.g., gap 435) in a range from 15 to 250 nm.

FIG. 5 presents a block diagram of a computer 500 that includes the electrical device 100. Embodiments of the device can includes one or more electrical circuits 102, 104, 106, 108, 120, 125 such as disclosed in the context of FIGS. 1A-4, and, at least one back-side metal track 110 connected to carry the global signal 115 within an individual circuit or between two circuits.

Another embodiment of the disclosure is a method of method of manufacturing an electrical device. FIG. 6 presents a flow diagram of a method of manufacturing the electrical device including any embodiments of the device disclosed in the context of FIGS. 1A-5.

With continuing reference to FIGS. 1A-6 throughout, the method 600 includes providing (step 605) a substrate 305 (e.g., a semiconductor substrate such as silicon dies or other die substrates familiar to those skilled in the pertinent art) having a frontside surface 307 and a backside surface 310, forming (step 610) a back-side insulating layer (e.g., layer 315 or 320; inorganic material layers such as silicon nitride or silicon dioxide, or organic polymer layers or combinations thereof as familiar to those skilled in the pertinent art)) on the backside surface. and forming (step 615) back-side metal tracks (e.g., generally tracks 110; copper or other types of low electrical resistivity metal tracks as familiar to those skilled in the pertinent art) in the back-side insulating layer.

The method 600 also includes providing (step 620) a signal source (any of circuits 104, 106, 108, 120) of the device 100 the signal source capable of producing a global signal (generally signal 115). The method 600 also includes providing (step 625) a signal receiver (any others of circuits 102, 104, 106, 108, 125) of the device 100, signal receiver capable of receiving the global signal. The method 600 also includes connecting (step 630) at least a portion (e.g., portions 322a, 322b, 322c, 322d, 322e) of at least one of the back-side metal tracks (e.g., back-side metal track 110b) to the signal source, wherein the portion of the least one of the back-side metal tracks can carry the global signal from the signal source along the portion of the back-side metal track towards the signal receiver of the device.

Those skilled in the pertinent art would be familiar with how to form insulating layers on the substrate surfaces (e.g., dielectric material deposition), metal layer deposition and patterning techniques (e.g., metal deposition and etching to shape metal tracks through the masks), and via formation processes, to form and connect the metal track portions.

In some such embodiments, the method 600 can further include forming (step 640) a second back-side insulating layer (e.g., layer 320) on the back-side insulating layer, forming (step 642) second back-side metal tracks (e.g., back-side metal tracks 110c) in the second back-side insulating layer and interconnecting (step 644) at least a portion (e.g., any of portions 405a…405d) of at least one of the second back-side metal tracks to the portion of the at least one of the back-side metal tracks so that the global signal 115 can be carried along the portion of the at least one of the second back-side metal tracks towards the signal receiver.

In some such embodiments, the method 600 can additionally or alternatively further include forming (step 650) a front-side insulating layer (e.g., layer 340) on the frontside surface 307, forming (step 652) front-side metal tracks (front-side metal tracks 110d) in the front-side insulating layer and interconnecting (step 654) at least a portion (e.g., any of portions 347a, 347b) of the at least one of the front-side metal tracks to the portion of the at least one of the back-side metal tracks so that the global signal 115 can be carried along the portion of the at least one of the front-side metal tracks towards the signal receiver.

Those skilled in the art to which this application relates will appreciate that other and further additions, deletions, substitutions and modifications may be made to the described embodiments.

What is claimed is:

1. An electrical device comprising:
a substrate having a frontside surface and a backside surface; and
a back-side insulating layer with back-side metal tracks therein, the back-side insulating layer located on the backside surface, wherein
at least a portion of at least one of the back-side metal tracks is connected to a signal source to carry a global signal along the portion of the at least one of the back-side metal tracks towards a signal receiver.

2. The device of claim 1, wherein the at least one back-side metal track is part of a set of back-side metal tracks in the back-side insulating layer.

3. The device of claim 2, wherein alternating ones of the back-side metal tracks in the set of back-side metal tracks are connected to an electrical ground.

4. The device of claim 1, further including a second back side insulating layer located on the backside substrate surface with another set of the back-side metal tracks located therein.

5. The device of claim 4, wherein alternating ones of the back-side metal tracks in the other set of back-side metal tracks in the second back side insulating layer are connected to an electrical ground.

6. The device of claim 1, further including a front-side insulating layer with front-side metal tracks therein, the front-side insulating layer located on the front-side surface, wherein at least a portion of at least one of the front-side metal tracks is connected to another of the signal source of the device to carry another of the global signal along the front-side metal track towards another of the signal receiver.

7. The device of claim 6, wherein the at least one front-side metal track is part of a set of front-side metal tracks in the front-side insulating layer.

8. The device of claim 7, wherein alternating ones of the front-side metal tracks in the set of front-side metal tracks are connected to an electrical ground.

9. The device of claim 6, further including a second front-side insulating layer with front-side metal tracks therein, the second front-side insulating layer located on the front-side substrate surface, wherein at least a portion of the at least one of the front-side metal tracks in the other set is connected to another of the signal source, to carry another of the global signal along the one front-side metal track of the other set to another of the signal receiver.

10. The device of claim 1, wherein the global signal carried along the at least one back-side metal track is also carried by one or more different back-side metal tracks or front-side metal tracks that are interconnected with each other.

11. The device of claim 1, further including another back-side metal track connected to carry a complement of the global signal, wherein the one back-side metal track and the other back-side metal track form a complementary pair of back-side metal tracks carrying complementary signals.

12. The device of claim 11, wherein the complementary pair of back-side metal tracks are part of a flying bit-line metal track assembly.

13. The device of claim 1, wherein the portions of the back-side metal tracks have a length value in a range from 1 to 50 µm.

14. The device of claim 1, wherein the portions of the back-side metal tracks have a width value in a range from 20 to 100 nm.

15. The device of claim 1, wherein the portions of the back-side metal tracks have a thickness value in a range from 10 to 50 nm.

16. The device of claim 1, wherein the portions of the back-side metal tracks are separated from adjacent ones of the back-side metal tracks by a gap distance value in a range from 15 to 250 nm.

17. The device of claim 1, wherein in the global signal is a bit-line write signal, a word line voltage, a pre-charge control signal, an input output signal or a clock signal, selected bit-line signal, or a selected amplified output signals.

18. The device of claim 1, wherein the electrical device is part of a computer, wherein the electrical device includes one or more of a memory circuit, a general input output circuit, a control circuit, a raw decoder circuit, an external source circuit or the external receiver circuit.

19. A method of manufacturing an electrical device, comprising:
providing a substrate having a frontside surface and a backside surface;
forming a back-side insulating layer on the backside surface;
forming back-side metal tracks in the back-side insulating layer;
providing a signal source of the device, the signal source capable of producing a global signal;
providing a signal receiver of the device, the signal receiver capable of receiving the global signal; and
connecting at least a portion of at least one of the back-side metal tracks to the signal source of the device, wherein the portion of the least one of the back-side metal track can carry the global signal from the signal source along the portion of the at least one of the back-side metal tracks towards the signal receiver.

20. The method of claim 19 further including:
forming a second back-side insulating layer on the back-side insulating layer;
forming second back-side metal tracks in the second back-side insulating layer; and
interconnecting at least a portion of at least one of the second back-side metal tracks to the portion of the at least one of the back-side metal tracks so that the global signal can be carried along the portion of the at least one of the second back-side metal tracks towards the signal receiver of the device.

21. The method of claim 19 further including:
forming a front-side insulating layer on the frontside surface;
forming front-side metal tracks in the front-side insulating layer; and
interconnecting at least a portion of the at least one of the front-side metal tracks to the portion of the at least one of the back-side metal tracks so that the global signal can be carried along the portion of the at least one of the front-side metal tracks towards the signal receiver.
